(19) United States
(12) Patent Application Publication
(10) Pub. No.: US 2023/0396235 A1
(43) Pub. Date: Dec. 7, 2023

(54) SURFACE ACOUSTIC WAVE DEVICES WITH HIGH VELOCITY HIGHER-ORDER MODE

(71) Applicants: SKYWORKS SOLUTIONS, INC., Irvine, CA (US); TOHOKU UNIVERSITY, Sendai-shi (JP)

(72) Inventors: Hiroyuki NAKAMURA, Osaka-Fu (JP); Rei GOTO, Osaka-Shi (JP); Keiichi MAKI, Suita-Shi (JP); Michio KADOTA, Sendai-Shi (JP); Shuji TANAKA, Sendai-Shi (JP)

(21) Appl. No.: 18/203,279

(22) Filed: May 30, 2023

Related U.S. Application Data
(60) Provisional application No. 63/346,957, filed on May 30, 2022.

(51) Int. Cl. H03H 9/25; H03H 9/64; H03H 9/02; H03H 3/08

(52) U.S. Cl. CPC H03H 9/25; H03H 3/08; H03H 9/02559; H03H 9/64

(57) ABSTRACT

In some embodiments, a surface acoustic wave device can include a piezoelectric substrate and an interdigital transducer electrode embedded in a surface of the piezoelectric substrate to support a high-order mode of a surface acoustic wave having a wavelength λ and a phase velocity greater than 8,000 m/s. Such a high-order mode can include a third-order mode, and the phase velocity can be at least 9,000 m/s. In some embodiments, such a surface acoustic wave device can be implemented in products such as a radio-frequency filter, a radio-frequency module and a wireless device.

### CROSS-REFERENCE TO RELATED APPLICATION(S)

This application claims priority to U.S. Provisional Application No. 63/346,957 filed May 30, 2022, entitled SURFACE ACOUSTIC WAVE DEVICES WITH HIGH VELOCITY HIGHER-ORDER MODE, the disclosure of which is hereby expressly incorporated by reference herein in its entirety.

### BACKGROUND

### Field

The present disclosure relates to surface acoustic wave devices and related methods.

### Description of the Related Art

A surface acoustic wave (SAW) resonator typically includes an interdigital transducer (IDT) electrode implemented on a surface of a piezoelectric layer. Such an electrode includes two interdigitized sets of fingers, and in such a configuration, the distance between two neighboring fingers of the same set is approximately the same as the wavelength A of a surface acoustic wave supported by the IDT electrode.

In many applications, the foregoing SAW resonator can be utilized as a radio-frequency (RF) filter based on the wavelength A. Such a filter can provide a number of desirable features.

### SUMMARY

In accordance with a number of implementations, the present disclosure relates to a surface acoustic wave device that includes a piezoelectric substrate and an interdigital transducer electrode embedded in a surface of the piezoelectric substrate to support a high-order mode of a surface acoustic wave having a wavelength A and a phase velocity greater than 8,000 m/s.

In some embodiments, the high-order mode can include a third-order mode. In some embodiments, the phase velocity can be at least 9,000 m/s. In some embodiments, the interdigital transducer electrode can include an upper surface that is approximately coplanar with the surface of the piezoelectric substrate.

In some embodiments, the piezoelectric substrate can include LiNbO₃ crystal having Euler angles (φ, θ, ψ). The angle θ can be in a range 100 degrees<θ<150 degrees.

In some embodiments, the interdigital transducer electrode can be formed from aluminum, molybdenum, copper, tungsten or platinum. In some embodiments, the interdigital transducer electrode can be formed from copper. Such a copper interdigital transducer electrode can have a thickness in a range of 0.16λ to 0.24λ.

In some embodiments, the surface acoustic wave device can further include a layer implemented over the piezoelectric substrate and the interdigital transducer electrode, and such a layer can be configured to provide improved temperature coefficient of frequency property of the surface acoustic wave device. In some embodiments, the layer can be formed from silicon dioxide (SiO₂). The layer can have a first surface that is coplanar with the upper surface of the interdigital transducer electrode and the surface of the piezoelectric substrate. The layer can have a second surface parallel to the first surface to define a thickness of the layer. A copper interdigital transducer electrode can be provided to have a thickness in a range of 0.24λ to 0.5λ.

In some implementations, the present disclosure relates to a radio-frequency filter that includes an input node for receiving a signal, an output node for providing a filtered signal, and a surface acoustic wave device implemented to be electrically between the input node and the output node. The surface acoustic wave device includes a piezoelectric substrate and an interdigital transducer electrode embedded in a surface of the piezoelectric substrate to support a high-order mode of a surface acoustic wave having a wavelength A and a phase velocity greater than 8,000 m/s.

In some embodiments, the high-order mode can include a third-order mode.

In some embodiments, the phase velocity can be at least 9,000 m/s.

In some embodiments, the interdigital transducer electrode can include an upper surface that is approximately coplanar with the surface of the piezoelectric substrate.

In some embodiments, the piezoelectric substrate can include LiNbO₃ crystal having Euler angles (φ, θ, ψ). The angle θ can be in a range 100 degrees<θ<150 degrees.

In some embodiments, the interdigital transducer electrode can be formed from aluminum, molybdenum, copper, tungsten or platinum.

In some embodiments, the radio-frequency filter can further include a layer implemented over the piezoelectric substrate and the interdigital transducer electrode, and configured to provide improved temperature coefficient of frequency property of the surface acoustic wave device. In some embodiments, the layer can be formed from silicon dioxide (SiO₂). The layer can have a first surface that is coplanar with the upper surface of the interdigital transducer electrode and the surface of the piezoelectric substrate. The layer can have a second surface parallel to the first surface to define a thickness of the layer.

In a number of implementations, the present disclosure relates to a radio-frequency module that includes a packaging substrate configured to receive a plurality of components, and a radio-frequency circuit implemented on the packaging substrate and configured to support either or both of transmission and reception of signals. The radio-frequency module further includes a radio-frequency filter configured to provide filtering for at least some of the signals. The radio-frequency filter includes a piezoelectric substrate and an interdigital transducer electrode embedded in a surface of the piezoelectric substrate to support a high-order mode of a surface acoustic wave having a wavelength A and a phase velocity greater than 8,000 m/s.

In some teachings, the present disclosure relates to a wireless device that includes a transceiver, an antenna, and a wireless system implemented to be electrically between the transceiver and the antenna. The wireless system includes a filter configured to provide filtering functionality for the wireless system. The filter includes a piezoelectric substrate and an interdigital transducer electrode embedded in a surface of the piezoelectric substrate to support a high-order mode of a surface acoustic wave having a wavelength A and a phase velocity greater than 8,000 m/s.

According to some teachings, the present disclosure relates to a method for fabricating a surface acoustic wave device. The method includes forming or providing a piezoelectric substrate, and embedding an interdigital transducer electrode in a surface of the piezoelectric substrate to support a high-order mode of a surface acoustic wave having a wavelength A and a phase velocity greater than 8,000 m/s.

In some embodiments, the high-order mode can include a third-order mode. In some embodiments, the phase velocity can be at least 9,000 m/s.

In some embodiments, the embedding of the interdigital transducer electrode can result in an upper surface that is approximately coplanar with the surface of the piezoelectric substrate.

In some embodiments, the piezoelectric substrate can include LiNbO₃ crystal having Euler angles (φ, θ, ψ). The angle θ can be in a range 100 degrees<θ<150 degrees.

In some embodiments, the interdigital transducer electrode can be formed from aluminum, molybdenum, copper, tungsten or platinum. In some embodiments, the interdigital transducer electrode can be formed from copper. The copper interdigital transducer electrode can have a thickness in a range of 0.16λ to 0.24λ.

In some embodiments, the method can further include implementing a layer over the piezoelectric substrate and the interdigital transducer electrode, such that the layer provides improved temperature coefficient of frequency property of the surface acoustic wave device. In some embodiments, the layer can be formed from silicon dioxide (SiO₂). The layer can have a first surface that is coplanar with the upper surface of the interdigital transducer electrode and the surface of the piezoelectric substrate. The layer can have a second surface parallel to the first surface to define a thickness of the layer. A copper interdigital transducer electrode having a thickness in a range of 0.24λ to 0.5λ can be provided.

In some embodiments, the surface acoustic device can be part of a radio-frequency filter.

For purposes of summarizing the disclosure, certain aspects, advantages and novel features of the inventions have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

FIG. 1A shows a plan view of a surface acoustic wave (SAW) device having a piezoelectric substrate and an interdigital transducer (IDT) electrode implemented thereon.

FIG. 1B shows a side sectional view of the SAW device of FIG. 1A.

FIG. 2 shows that in some embodiments, the SAW device of FIGS. 1A and 1B can generate a higher order mode.

FIG. 3A shows a plot of electromechanical coupling coefficient k² as cut angle θ is swept through a range of 70 degrees to 170 degrees in 10-degree increments.

FIG. 3B shows plots of quality factors Qs and Qp at series and parallel resonance frequencies, as the cut angle θ is swept through a range of 0 degrees to 170 degrees in 10-degree increments.

FIG. 4 shows various plots related to a SAW device having an embedded IDT configuration.

FIG. 5 shows that in some embodiments, a SAW device can include an overcoat layer provided over an IDT electrode and a piezoelectric substrate to improve temperature coefficient of frequency (TCF) property of the SAW device.

FIG. 6 shows third order mode admittance modulus plots, plots of real part of the admittance for the third order mode responses and Q plots obtained from real admittance part peaks for a SAW device similar to the example SAW device of FIG. 5 but with different cut angles θ of Euler angles (0, θ, 0) of LN substrate.

FIG. 7 shows third order mode admittance modulus plots, plots of real part of the admittance for the third order mode responses and Q plots obtained from real admittance part peaks for a SAW device similar to the example SAW device of FIG. 5 but with different thickness values (h) of the IDT electrodes.

FIG. 8 shows that in some embodiments, multiple units of SAW resonators can be fabricated while in an array form.

FIG. 9 shows that in some embodiments, a SAW resonator having one or more features as described herein can be implemented as a part of a packaged device.

FIG. 10 shows that in some embodiments, the SAW resonator based packaged device of FIG. 9 can be a packaged filter device.

FIG. 11 shows that in some embodiments, a radio-frequency (RF) module can include an assembly of one or more RF filters.

FIG. 12 depicts an example wireless device having one or more advantageous features described herein.

### DETAILED DESCRIPTION OF SOME EMBODIMENTS

The headings provided herein, if any, are for convenience only and do not necessarily affect the scope or meaning of the claimed invention.

In some wireless applications, frequency bands in a range from 700 MHz to 3 GHz used by smartphones and the like are significantly congested. To solve this problem, fifth generation mobile communication system (5G) utilizes frequency bands in a range from 3.6 GHz to 4.9 GHz, and a further next generation may be planned to use frequency bands having frequencies of 6 GHz or greater.

To enable use of the foregoing frequency bands, typical acoustic wave devices such as surface acoustic wave (SAW) devices cannot reduce the wavelength (A) provided by an interdigital transducer (IDT) electrode due to limitations of electric power resistance and manufacturing technologies; and thus, there is a limitation in using higher frequencies.

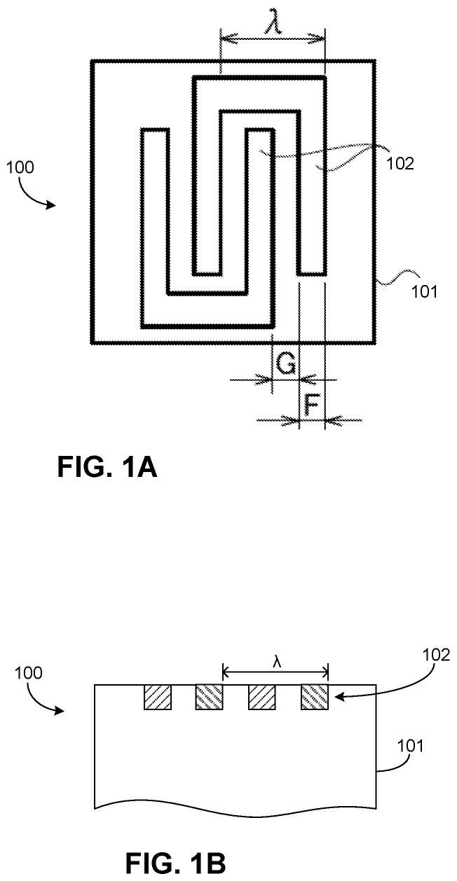

FIG. 1A shows a plan view of a surface acoustic wave (SAW) device 100 having a piezoelectric substrate 101 and an interdigital transducer (IDT) electrode 102 implemented thereon. FIG. 1B shows a side sectional view of the SAW device 100 of FIG. 1A. As shown in FIG. 1B, the IDT electrode 102 can be embedded within the piezoelectric substrate 101 such that the upper surface of the IDT electrode 102 (when viewed as in FIG. 1B) and the upper surface of the piezoelectric substrate 101 (when viewed as in FIG. 1B) are approximately coplanar. It will be understood that while various examples are described herein in the context of such a coplanar configuration, one or more features of the present disclosure can also be implemented in a configuration where the upper surfaces of the IDT electrode and the piezoelectric substrate are not coplanar.

Referring to FIGS. 1A and 1B, the distance between two neighboring fingers of the IDT electrode 102 is approximately the same as the wavelength A of a surface acoustic wave associated with the IDT electrode 102. Further, each finger of the IDT electrode 102 is shown to have a lateral width of F, and a gap distance of G is shown to be provided between two interdigitized neighboring fingers.

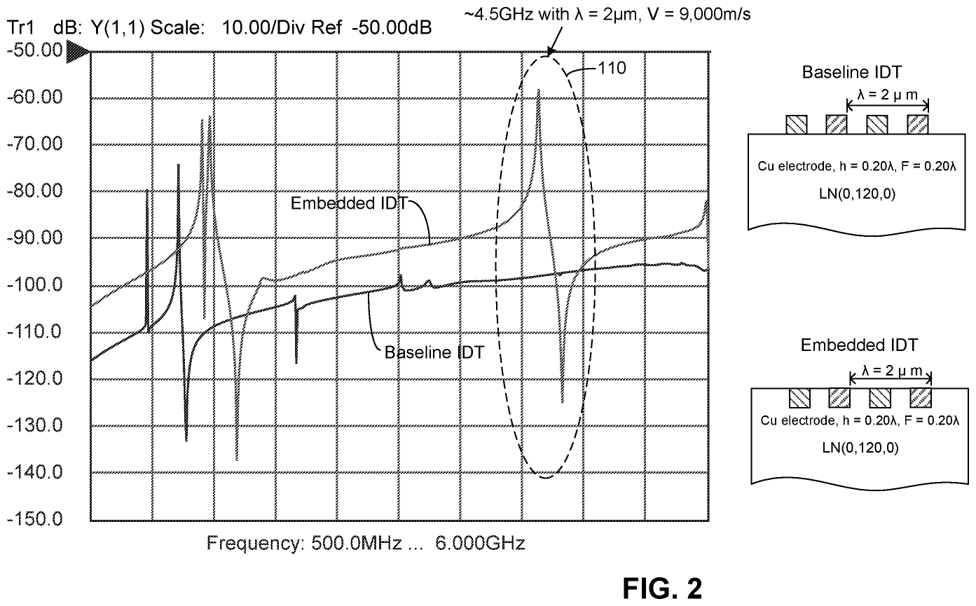

FIG. 2 shows that in some embodiments, the SAW device 100 of FIGS. 1A and 1B can generate a higher order mode. In the example of FIG. 2, such a SAW device (100 of FIGS. 1A and 1B) is referred to as Embedded IDT configuration which is compared to Baseline IDT configuration where the corresponding IDT electrode is not embedded. For both of the Baseline IDT and Embedded IDT configurations, the piezoelectric substrates are formed from LiNbO₃ (also referred to herein as LN) each having example Euler angles (0, 120, 0). Further, the IDT electrode of each of the Baseline IDT and Embedded IDT configurations is formed from copper (Cu) and configured to provide a wavelength λ of 2 μm, a width F of 0.20λ, and a thickness h of 0.20λ.

Configured in the foregoing manner, and by way of an example admittance modulus plot, FIG. 2 shows that a third order mode (indicated as 110) is generated by the Embedded IDT configuration. Such a third order mode is shown to be at about 4.5 GHz with the wavelength A of 2 μm, thereby providing a phase velocity V=fλ=9,000 m/s. It is noted that in some embodiments, such a third mode can be utilized for high frequency filter applications.

In some embodiments, a SAW device as described herein can be configured to support a third order mode of a surface acoustic wave having a phase velocity greater than 8,000 m/s. In some embodiments, such a surface acoustic wave can have a phase velocity of at least 9,000 m/s.

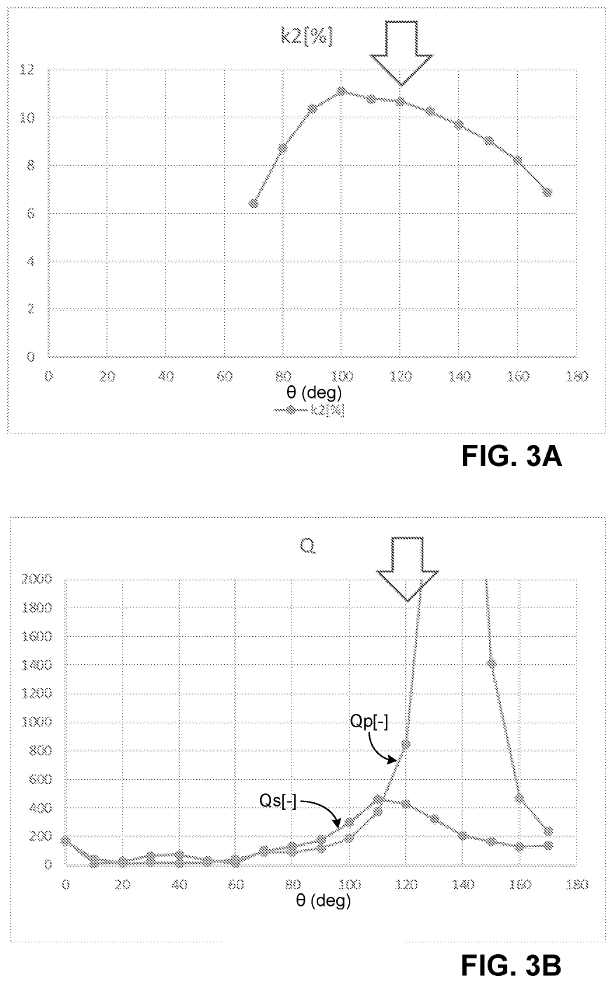

FIGS. 3A and 3B show an example of a preferred range of piezoelectric substrate cut angle θ of Euler angles (φ, θ, ψ). More particularly, FIG. 3A shows a plot of electromechanical coupling coefficient k² as the cut angle θ is swept through a range of 70 degrees to 170 degrees in 10-degree increments. One can see that k² has a maximum value when θ is 100 degrees. One can also see that for the Euler angles configuration of (0, 120, 0) of the Embedded IDT configuration of FIG. 2, k² has a value at θ=120 degrees that is relatively large but slightly less than the maximum value (when θ=100 degrees).

FIG. 3B shows plots of quality factors Qs and Qp at the series and parallel resonance frequencies, as the cut angle θ is swept through a range of 0 degrees to 170 degrees in 10-degree increments. One can see that Qs has a maximum value when θ is 110 degrees. One can also see that for the Euler angles configuration of (0, 120, 0) of the Embedded IDT configuration of FIG. 2, Qs has a value at θ=120 degrees that is relatively large but slightly less than the maximum value (when θ=110 degrees). One can also see that Qs begins to increase significantly when θ is 80 degrees, and returns to a relatively low value when θ is 150 degrees.

With respect to Qp, one can see that the value of Qp begins to increase sharply when θ is 100 degrees, and returns to a relatively low value when θ is 170 degrees.

Based on the example of FIG. 3B, one can see that in some embodiments, a range of cut angle θ between 100 degrees and 150 degrees can be desirable. Such a range of cut angle θ also provides a range of relatively high values of coupling coefficient k² as shown in FIG. 3A.

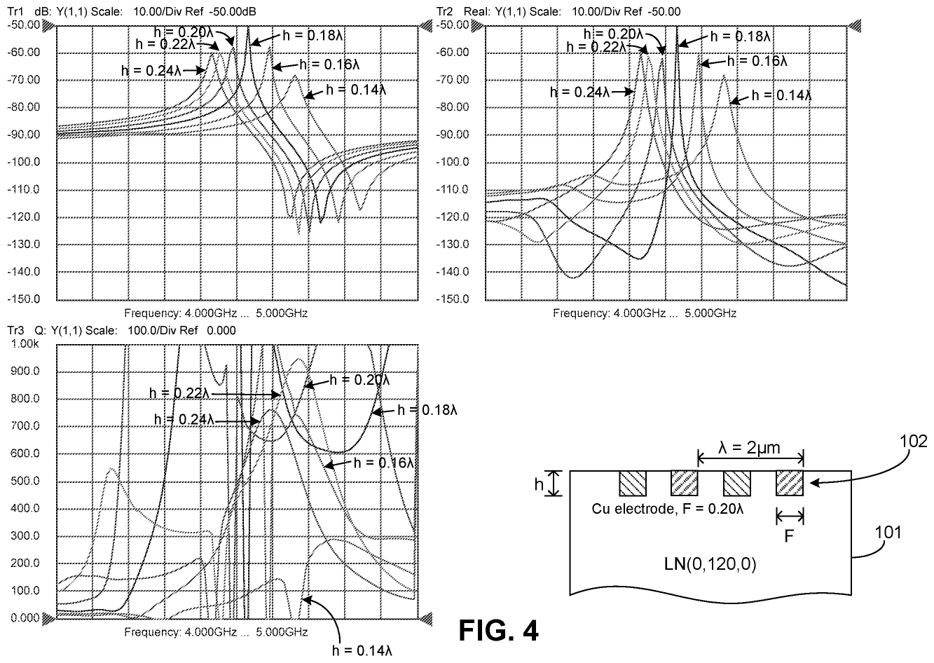

FIG. 4 shows various plots related to a SAW device having an Embedded IDT configuration, demonstrating how various parameters of such a SAW device vary with thickness h of the embedded IDT electrode 102. In the example of FIG. 4, the embedded IDT electrode 102 is shown to be from copper (Cu) and configured to provide a wavelength A of 2 μm, and a width F of 0.20λ. Further, the piezoelectric substrate 101 formed from LN is shown to have Euler angles (0, 120, 0).

In FIG. 4, the upper left panel shows third order mode admittance modulus plots for the above-referenced SAW device with thickness h of 0.14λ, 0.16λ, 0.20λ, 0.22λ and 0.24λ. The upper right panel shows real part of the admittance for the third order mode responses for the same thickness values h, and the lower left panel shows Q plots obtained from such real admittance part peaks. One can see that the various responses, including the Q response, are sensitive to the IDT electrode thickness h.

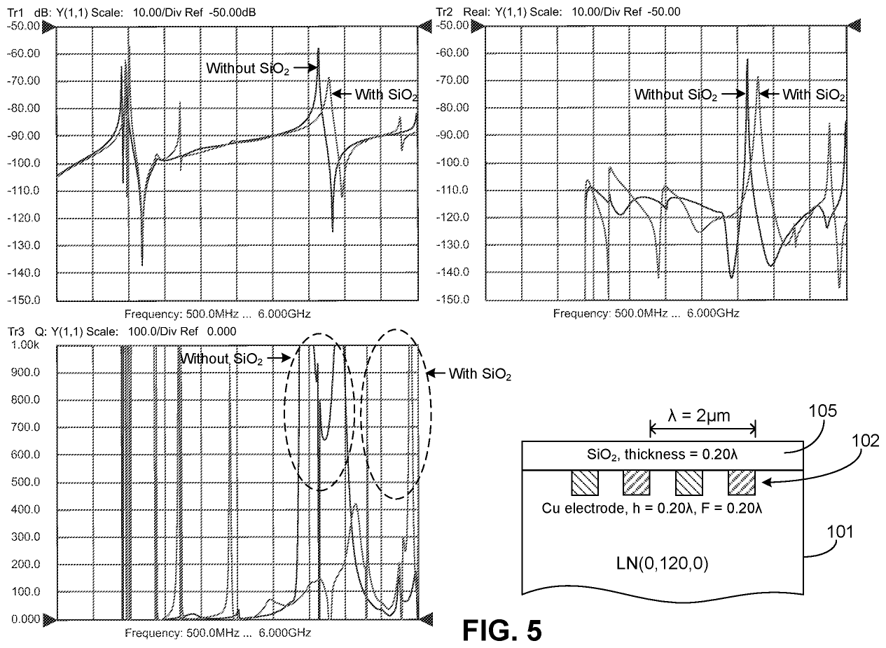

FIG. 5 shows that in some embodiments, a SAW device can include an overcoat layer 105 provided over an IDT electrode 102 and a piezoelectric substrate 101 to improve temperature coefficient of frequency (TCF) property of the SAW device. In the example of FIG. 5, the IDT electrode 102 is embedded within the piezoelectric substrate 101 such that the upper surface of the IDT electrode 102 (when viewed as in FIG. 5) and the upper surface of the piezoelectric substrate 101 are approximately coplanar. Thus, in some embodiments, the overcoat layer 105 can completely cover the IDT electrode 102.

In some embodiments the overcoat layer 105 can be formed from material such as silicon dioxide (SiO₂) having a thickness. In FIG. 5, the example SiO₂ overcoat layer 105 is shown to have a thickness of 0.20λ, where the wavelength A is 2 μm defined by the example embedded IDT electrode 102 formed from copper (Cu) and having a width F of 0.20λ and a thickness of 0.20λ. In the example of FIG. 5, the piezoelectric substrate 101 is formed from LN having Euler angles (0, 120, 0).

FIG. 5 shows various plots related to the foregoing SAW device having the SiO₂ overcoat layer 105 compared to a similar SAW device without a SiO₂ overcoat layer. In FIG. 5, the upper left panel shows third order mode admittance modulus plots for the above-referenced SAW devices with and without SiO₂ overcoat layer. The upper right panel shows real part of the admittance for the third order mode responses for the same SAW devices with and without SiO₂ overcoat layer, and the lower left panel shows Q plots obtained from such real admittance part peaks. It is noted that configured in the foregoing manner, implementation of a SiO₂ overcoat layer can improve TCF performance, but the quality factor Q is shown to be degraded.

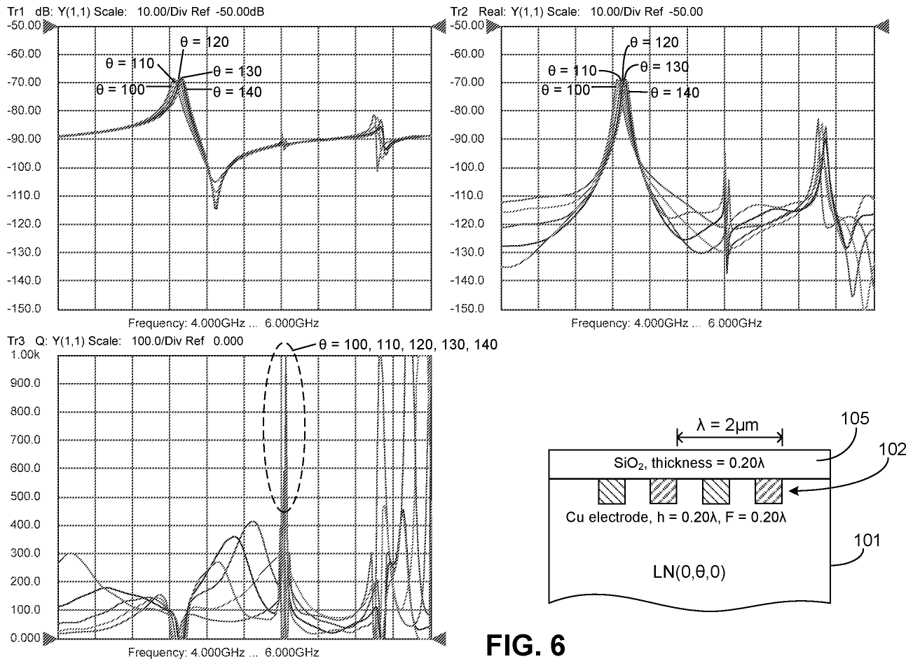

FIG. 6 shows third order mode admittance modulus plots (upper left panel), plots of real part of the admittance for the third order mode responses (upper right panel) and Q plots obtained from such real admittance part peaks (lower left panel) for a SAW device similar to the example SAW device of FIG. 5 but with different cut angles θ of the Euler angles (0, θ, 0) of the LN substrate 101. More particularly, the cut angles θ in FIG. 6 are 100, 110, 120, 130 and 140 degrees. As shown in the Q plots of FIG. 6, the Q performance does not vary greatly by varying the angle θ of the LN substrate.

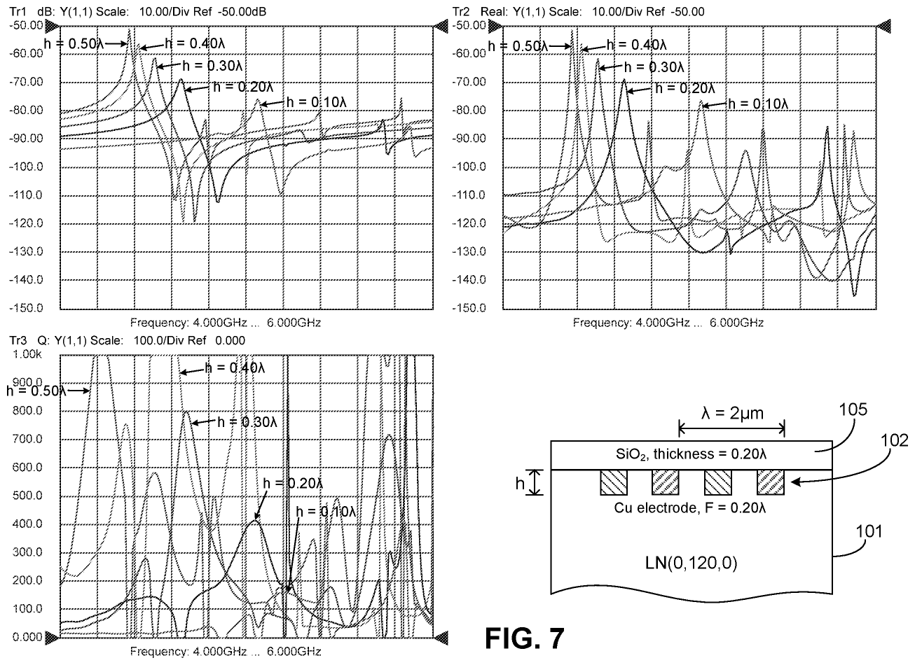

FIG. 7 shows third order mode admittance modulus plots (upper left panel), plots of real part of the admittance for the third order mode responses (upper right panel) and Q plots obtained from such real admittance part peaks (lower left panel) for a SAW device similar to the example SAW device of FIG. 5 but with different thickness values (h) of the IDT electrodes 102. More particularly, the thickness values (h) in FIG. 7 are 0.10λ, 0.20λ, 0.30λ, 0.40λ and 0.50λ. As shown in the Q plots of FIG. 7, the Q performance is shown to improve with thicker Cu IDT electrodes.

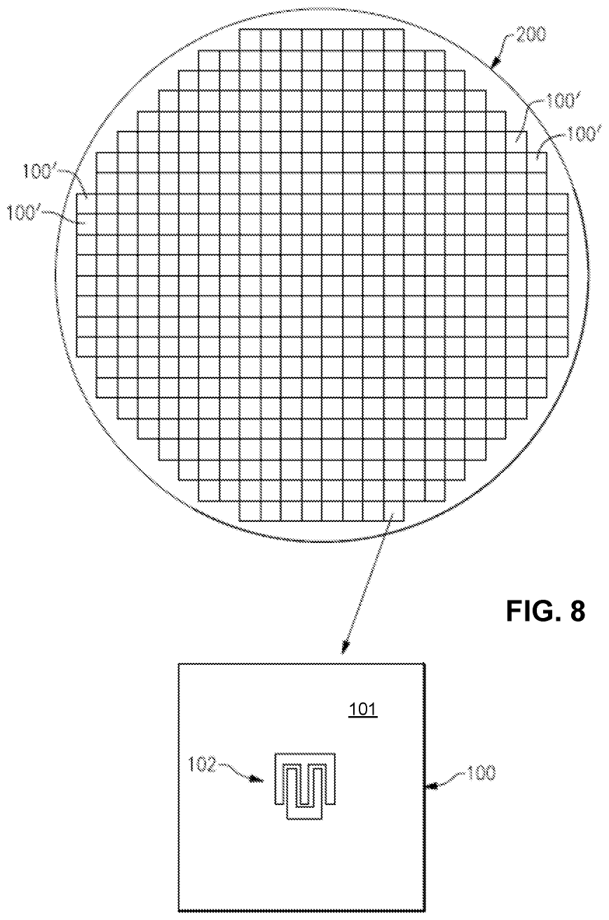

In some embodiments, a SAW resonator having one or more features as described herein can be implemented as a product, and such a product can be included in another product. Examples of such different products are described in reference to FIGS. 8-12.

FIG. 8 shows that in some embodiments, multiple units of SAW resonators can be fabricated while in an array form. For example, a wafer 200 can include an array of units 100′, and such units can be processed through a number of process steps while joined together.

Upon completion of process steps in the foregoing wafer format, the array of units 100′ can be singulated to provide multiple SAW resonators 100. FIG. 8 depicts one of such SAW resonators 100, and such a SAW resonator can include one or more features as described herein.

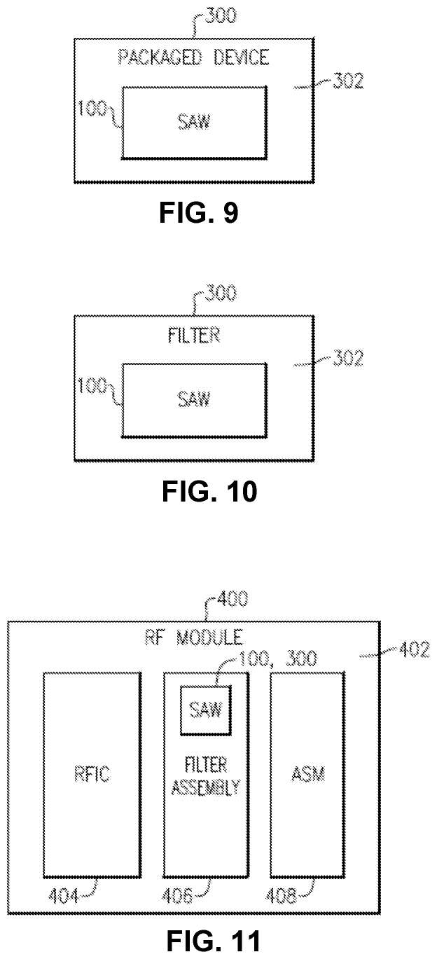

FIG. 9 shows that in some embodiments, a SAW resonator 100 having one or more features as described herein can be implemented as a part of a packaged device 300. Such a packaged device can include a packaging substrate 302 configured to receive and support one or more components, including the SAW resonator 100.

FIG. 10 shows that in some embodiments, the SAW resonator based packaged device 300 of FIG. 9 can be a packaged filter device 300. Such a filter device can include a packaging substrate 302 suitable for receiving and supporting a SAW resonator 100 configured to provide a filtering functionality such as RF filtering functionality.

FIG. 11 shows that in some embodiments, a radio-frequency (RF) module 400 can include an assembly 406 of one or more RF filters. Such filter(s) can be SAW resonator based filter(s) 100, packaged filter(s) 300, or some combination thereof. In some embodiments, the RF module 400 of FIG. 11 can also include, for example, an RF integrated circuit (RFIC) 404, and an antenna switch module (ASM) 408. Such a module can be, for example, a front-end module configured to support wireless operations. In some embodiments, some of all of the foregoing components can be mounted on and supported by a packaging substrate 402.

In some implementations, a device and/or a circuit having one or more features described herein can be included in an RF device such as a wireless device. Such a device and/or a circuit can be implemented directly in the wireless device, in a modular form as described herein, or in some combination thereof. In some embodiments, such a wireless device can include, for example, a cellular phone, a smart-phone, a hand-held wireless device with or without phone functionality, a wireless tablet, etc.

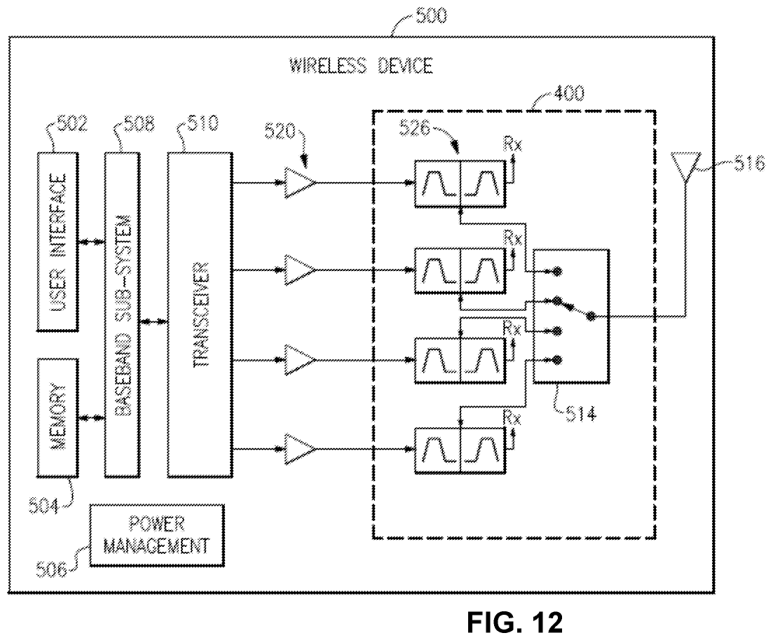

FIG. 12 depicts an example wireless device 500 having one or more advantageous features described herein. In the context of a module having one or more features as described herein, such a module can be generally depicted by a dashed box 400, and can be implemented as, for example, a front-end module (FEM). In such an example, one or more SAW filters as described herein can be included in, for example, an assembly of filters such as duplexers 526.

Referring to FIG. 12, power amplifiers (PAs) 520 can receive their respective RF signals from a transceiver 510 that can be configured and operated in known manners to generate RF signals to be amplified and transmitted, and to process received signals. The transceiver 510 is shown to interact with a baseband sub-system 408 that is configured to provide conversion between data and/or voice signals suitable for a user and RF signals suitable for the transceiver 510. The transceiver 510 can also be in communication with a power management component 506 that is configured to manage power for the operation of the wireless device 500. Such power management can also control operations of the baseband sub-system 508 and the module 400.

The baseband sub-system 508 is shown to be connected to a user interface 502 to facilitate various input and output of voice and/or data provided to and received from the user. The baseband sub-system 508 can also be connected to a memory 504 that is configured to store data and/or instructions to facilitate the operation of the wireless device, and/or to provide storage of information for the user.

In the example wireless device 500, outputs of the PAs 520 are shown to be routed to their respective duplexers 526. Such amplified and filtered signals can be routed to an antenna 516 through an antenna switch 514 for transmission. In some embodiments, the duplexers 526 can allow transmit and receive operations to be performed simultaneously using a common antenna (e.g., 516). In FIG. 12, received signals are shown to be routed to “Rx” paths (not shown) that can include, for example, a low-noise amplifier (LNA).

Although various examples are described herein in the context of a piezoelectric substrate including LiNbO₃ (LN), it will be understood that one or more features of the present disclosure can also be implemented utilizing other piezoelectric substrates such as LiTaO₃ (LT).

Unless the context clearly requires otherwise, throughout the description and the claims, the words “comprise,” “comprising,” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Where the context permits, words in the above Description using the singular or plural number may also include the plural or singular number respectively. The word “or” in reference to a list of two or more items, that word covers all of the following interpretations of the word: any of the items in the list, all of the items in the list, and any combination of the items in the list.

The above detailed description of embodiments of the invention is not intended to be exhaustive or to limit the invention to the precise form disclosed above. While specific embodiments of, and examples for, the invention are described above for illustrative purposes, various equivalent modifications are possible within the scope of the invention, as those skilled in the relevant art will recognize. For example, while processes or blocks are presented in a given order, alternative embodiments may perform routines having steps, or employ systems having blocks, in a different order, and some processes or blocks may be deleted, moved, added, subdivided, combined, and/or modified. Each of these processes or blocks may be implemented in a variety of different ways. Also, while processes or blocks are at times shown as being performed in series, these processes or blocks may instead be performed in parallel, or may be performed at different times.

The teachings of the invention provided herein can be applied to other systems, not necessarily the system described above. The elements and acts of the various embodiments described above can be combined to provide further embodiments.

While some embodiments of the inventions have been described, these embodiments have been presented by way of example only, and are not intended to limit the scope of the disclosure. Indeed, the novel methods and systems described herein may be embodied in a variety of other forms; furthermore, various omissions, substitutions and changes in the form of the methods and systems described herein may be made without departing from the spirit of the disclosure. The accompanying claims and their equivalents are intended to cover such forms or modifications as would fall within the scope and spirit of the disclosure.

1. A surface acoustic wave device comprising:
a piezoelectric substrate; and
an interdigital transducer electrode embedded in a surface of the piezoelectric substrate to support a high-order mode of a surface acoustic wave having a wavelength λ and a phase velocity greater than 8,000 m/s.

2. The surface acoustic wave device of claim 1 wherein the high-order mode includes a third-order mode.

3. The surface acoustic wave device of claim 1 wherein the phase velocity is at least 9,000 m/s.

4. The surface acoustic wave device of claim 1 wherein the interdigital transducer electrode includes an upper surface that is approximately coplanar with the surface of the piezoelectric substrate.

5. The surface acoustic wave device of claim 1 wherein the piezoelectric substrate includes LiNbO₃ crystal having Euler angles (φ, θ, ψ).

6. The surface acoustic wave device of claim 5 wherein the angle θ is in a range 100 degrees<θ<150 degrees.

7. The surface acoustic wave device of claim 1 wherein the interdigital transducer electrode is formed from aluminum, molybdenum, copper, tungsten or platinum.

8. The surface acoustic wave device of claim 7 wherein the interdigital transducer electrode is formed from copper.

9. The surface acoustic wave device of claim 8 wherein the copper interdigital transducer electrode has a thickness in a range of 0.16λ to 0.24λ.

10. The surface acoustic wave device of claim 1 further comprising a layer implemented over the piezoelectric substrate and the interdigital transducer electrode, the layer configured to provide improved temperature coefficient of frequency property of the surface acoustic wave device.

11. The surface acoustic wave device of claim 10 wherein the layer is formed from silicon dioxide (SiO₂).

12. The surface acoustic wave device of claim 10 wherein the layer has a first surface that is coplanar with the upper surface of the interdigital transducer electrode and the surface of the piezoelectric substrate.

13. The surface acoustic wave device of claim 12 wherein the layer has a second surface parallel to the first surface to define a thickness of the layer.

14. The surface acoustic wave device of claim 13 wherein the copper interdigital transducer electrode has a thickness in a range of 0.24λ to 0.5λ.

15. A radio-frequency filter comprising:
an input node for receiving a signal;
an output node for providing a filtered signal; and
a surface acoustic wave device implemented to be electrically between the input node and the output node, the surface acoustic wave device including a piezoelectric substrate and an interdigital transducer electrode embedded in a surface of the piezoelectric substrate to support a high-order mode of a surface acoustic wave having a wavelength A and a phase velocity greater than 8,000 m/s.

16. The radio-frequency filter of claim 15 wherein the high-order mode includes a third-order mode.

17. (canceled)

18. (canceled)

19. (canceled)

20. (canceled)

21. (canceled)

22. The radio-frequency filter of claim 15 further comprising a layer implemented over the piezoelectric substrate and the interdigital transducer electrode, the layer configured to provide improved temperature coefficient of frequency property of the surface acoustic wave device.

23. The radio-frequency filter of claim 22 wherein the layer is formed from silicon dioxide (SiO₂).

24. The radio-frequency filter of claim 22 wherein the layer has a first surface that is coplanar with the upper surface of the interdigital transducer electrode and the surface of the piezoelectric substrate.

25. (canceled)

26. A radio-frequency module comprising:
a packaging substrate configured to receive a plurality of components;
a radio-frequency circuit implemented on the packaging substrate and configured to support either or both of transmission and reception of signals; and
a radio-frequency filter configured to provide filtering for at least some of the signals, the radio-frequency filter including a piezoelectric substrate and an interdigital transducer electrode embedded in a surface of the piezoelectric substrate to support a high-order mode of a surface acoustic wave having a wavelength λ and a phase velocity greater than 8,000 m/s.

27. (canceled)

28. (canceled)

29. (canceled)

30. (canceled)

31. (canceled)

32. (canceled)

33. (canceled)

34. (canceled)

35. (canceled)

36. (canceled)

37. (canceled)

38. (canceled)

39. (canceled)

40. (canceled)

41. (canceled)

42. (canceled)
